(19) United States
(12) Patent Application Publication
(10) Pub. No.: US 2024/0324317 A1
(43) Pub. Date: Sep. 26, 2024

(54) DISPLAY APPARATUS AND METHOD OF MANUFACTURING THE SAME

(71) Applicant: Samsung Display Co., Ltd., Yongin-Si (KR)

(72) Inventors: Sewan Son, Yongin-si (KR); Wangwoo Lee, Yongin-si (KR); Sungho Kim, Yongin-si (KR); Minwoo Woo, Yongin-si (KR); Kwanhee Lee, Yongin-si (KR); Jiseon Lee, Yongin-si (KR); Sugwoo Jung, Yongin-si (KR); Hyeri Cho, Yongin-si (KR)

(21) Appl. No.: 18/614,539

(22) Filed: Mar. 22, 2024

(30) Foreign Application Priority Data
Mar. 24, 2023 (KR) 10-2023-0039060
Sep. 18, 2023 (KR) 10-2023-0124260

(51) Int. Cl. H10K 59/122; H10K 59/12; H10K 59/80; H10K 59/88; H10K 71/60

(52) U.S. Cl. CPC H10K 59/122; H10K 59/1201; H10K 59/873; H10K 59/88; H10K 71/60

(57) ABSTRACT

A display apparatus includes a pixel electrode, a pixel definition layer disposed over the pixel electrode and including a first opening exposing a center portion of the pixel electrode, a bank layer disposed over the pixel definition layer and including a second opening exposing the center portion of the pixel electrode, a first pixel protection layer and a second pixel protection layer arranged between the pixel definition layer and the bank layer, an intermediate layer disposed over the pixel electrode, an opposite electrode disposed over the intermediate layer, and an encapsulation layer disposed over the bank layer and the opposite electrode.

### CROSS-REFERENCE TO RELATED APPLICATION

This application is based on and claims priority under 35 U.S.C. §119 to Korean Patent Application No. 10-2023-0039060, filed on Mar. 24, 2023, and Korean Patent Application No. 10-2023-0124260, filed on Sep. 18, 2023, in the Korean Intellectual Property Office, the disclosures of which are incorporated by reference herein in their entirety.

### BACKGROUND

### 1. Field

One or more embodiments relate to a display apparatus and a method of manufacturing the same.

### 2. Description of the Related Art

Recently, display apparatuses have been used for various purposes. Also, as display apparatuses have become thinner and lighter, their range of use has widened.

In general, a display apparatus includes a plurality of pixels that receive an electrical signal to emit light to display an image. A pixel of an organic light emitting display (OLED) apparatus includes an organic light emitting diode as a display element and a driving circuit for controlling an electrical signal applied to the display element. The driving circuit includes a thin film transistor (TFT), a storage capacitor, and a plurality of signal lines. A plurality of signal lines are configured to provide a data signal, a driving voltage, a common voltage, and the like to a driving circuit of each pixel.

### SUMMARY

In a display apparatus of the related art, there is a limitation in that an opposite electrode is disconnected or a pixel electrode is damaged in a manufacturing process.

One or more embodiments include a display apparatus that displays a high-quality image. However, these problems are merely examples and the scope of the disclosure is not limited thereto.

Additional aspects will be set forth in part in the description which follows and, in part, will be apparent from the description, or may be learned by practice of the presented embodiments of the disclosure.

According to one or more embodiments, a display apparatus includes a pixel electrode, a pixel definition layer disposed over the pixel electrode and including a first opening exposing a center portion of the pixel electrode, a bank layer disposed over the pixel definition layer and including a second opening exposing the center portion of the pixel electrode, a first pixel protection layer and a second pixel protection layer arranged between the pixel definition layer and the bank layer, an intermediate layer disposed over the pixel electrode, an opposite electrode disposed over the intermediate layer, and an encapsulation layer disposed over the bank layer and the opposite electrode.

The display apparatus may further include a dummy intermediate layer and a dummy opposite electrode located between the bank layer and the encapsulation layer, wherein the dummy intermediate layer may include the same material as the intermediate layer, and the dummy opposite electrode may include the same material as the opposite electrode.

The bank layer may include a first subbank layer and a second subbank layer disposed over the first subbank layer, the first subbank layer may include a first subopening exposing the center portion of the pixel electrode, the second subbank layer may include a second subopening exposing the center portion of the pixel electrode, and the second subbank layer may include a tip protruding toward a center of the first subopening from a point where a side surface of the first subbank layer and a bottom surface of the second subbank layer meet each other.

The first subbank layer and the second subbank layer may include different materials.

The opposite electrode may directly contact a side surface of the first subbank layer.

A width of the first subopening at an interface between the first subbank layer and the second subbank layer may be greater than a width of the first subopening at an interface between the first subbank layer and the second pixel protection layer.

The tip may surround the center portion of the pixel electrode.

The first pixel protection layer and the second pixel protection layer may include materials with different etch rates.

The first pixel protection layer may include conductive oxide, and the second pixel protection layer may include silicon oxide, silicon nitride, or silicon oxynitride.

According to one or more embodiments, a method of manufacturing a display apparatus includes forming a pixel electrode over a substrate, forming a pixel definition layer including a first opening exposing a center portion of the pixel electrode over the pixel electrode, forming a first pixel protection layer over the pixel definition layer and the pixel electrode, forming a second pixel protection layer over the first pixel protection layer, forming a bank layer over the second pixel protection layer, sequentially removing a portion of the bank layer, a portion of the second pixel protection layer, and a portion of the first pixel protection layer to expose the center portion of the pixel electrode, forming an intermediate layer over the pixel electrode, forming an opposite electrode over the intermediate layer, and forming an encapsulation layer over the opposite electrode.

The forming of the bank layer may include forming a first subbank layer over the second pixel protection layer, and forming a second subbank layer over the first subbank layer, and the removing of a portion of the bank layer may include removing a portion of the first subbank layer and a portion of the second subbank layer such that the second subbank layer includes a tip protruding toward the center portion of the pixel electrode from a point where a side surface of the first subbank layer and a bottom surface of the second subbank layer meet each other.

The opposite electrode may directly contact a side surface of the first subbank layer. The first subbank layer and the second subbank layer may include different materials.

The removing of a portion of the first subbank layer and a portion of the second subbank layer may include forming a first subopening formed through the first subbank layer, and a width of the first subopening at an interface of the first subbank layer and the second subbank layer may be greater than a width of the first subopening at an interface between the first subbank layer and the second pixel protection layer.

The first pixel protection layer and the second pixel protection layer may include materials with different etch rates.

The first pixel protection layer may include conductive oxide, and the second pixel protection layer may include at least one of silicon oxide, silicon nitride, and silicon oxynitride.

According to one or more embodiments, a display apparatus includes a pixel electrode, a pixel definition layer disposed over the pixel electrode and including an opening exposing a center portion of the pixel electrode, an auxiliary electrode disposed to be spaced apart from the pixel electrode, a first pixel protection layer and a second pixel protection layer arranged below the auxiliary electrode, an intermediate layer disposed over the pixel electrode, and an opposite electrode disposed over the intermediate layer, wherein the auxiliary electrode is electrically connected to the opposite electrode.

The auxiliary electrode may include a main electrode layer and an upper auxiliary electrode layer disposed over the main electrode layer, and a width of the upper auxiliary electrode layer may be greater than a width of the main electrode layer at an interface between the upper auxiliary electrode layer and the main electrode layer.

A side surface of the main electrode layer and the opposite electrode may contact each other.

The first pixel protection layer may include conductive oxide, and the second pixel protection layer may include silicon oxide, silicon nitride, or silicon oxynitride.

Other aspects, features, and advantages other than those described above will become apparent from the accompanying drawings, the appended claims, and the detailed description of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a perspective view schematically illustrating a display apparatus according to an embodiment;

FIG. 2 is a plan view schematically illustrating a display panel included in a display apparatus according to an embodiment;

FIGS. 3A and 3B are equivalent circuit diagrams schematically illustrating a pixel included in a display apparatus according to embodiments;

FIGS. 4A, 4B, 4C, 4D, 4E, 4F, 4G, 4H, 41 and 4J are cross-sectional views schematically illustrating some operations of a display apparatus manufacturing method according to an embodiment;

FIG. 5 is a cross-sectional view illustrating a stack structure of a light emitting diode according to an embodiment;

FIG. 6 is a cross-sectional view schematically illustrating a display apparatus according to an embodiment;

FIG. 7 is a plan view schematically illustrating a display apparatus according to an embodiment; and

FIG. 8 is a cross-sectional view schematically illustrating a display apparatus according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

The disclosure may include various embodiments and modifications, and particular embodiments thereof are illustrated in the drawings and will be described herein in detail. The effects and features of the disclosure and the accomplishing methods thereof will become apparent from the embodiments described below in detail with reference to the accompanying drawings. However, the disclosure is not limited to the embodiments described below, and may be embodied in various modes.

Hereinafter, embodiments will be described in detail with reference to the accompanying drawings, and in the following description, like reference numerals will denote like elements and redundant descriptions thereof will be omitted.

It will be understood that although terms such as “first” and “second” may be used herein to describe various components, these components should not be limited by these terms and these terms are only used to distinguish one component from another component.

As used herein, the singular forms “a,” “an,” and “the” are intended to include the plural forms as well, unless the context clearly indicates otherwise.

Also, it will be understood that the terms “comprise,” “include,” and “have” used herein specify the presence of stated features or components, but do not preclude the presence or addition of one or more other features or components.

It will be understood that when a layer, region, or component is referred to as being “on” another layer, region, or component, it may be “directly on” the other layer, region, or component or may be “indirectly on” the other layer, region, or component with one or more intervening layers, regions, or components therebetween.

It will be understood that when a layer, region, or component is referred to as being “connected to” another layer, region, or component, it may be “directly connected to” the other layer, region, or component or may be “indirectly connected to” the other layer, region, or component with one or more intervening layers, regions, or components therebetween. For example, it will be understood that when a layer, region, or component is referred to as being “electrically connected to” another layer, region, or component, it may be “directly electrically connected to” the other layer, region, or component and/or may be “indirectly electrically connected to” the other layer, region, or component with one or more intervening layers, regions, or components therebetween.

As used herein, “A and/or B” represents the case of A, B, or A and B. Also, “at least one of A and B” represents the case of A, B, or A and B.

As used herein, the x axis, the y axis, and the z axis are not limited to three axes of the rectangular coordinate system, and may be interpreted in a broader sense. For example, the x-axis, y-axis, and z-axis may be perpendicular to each other or may refer to different directions that are not perpendicular to each other.

The term “about” or “approximately” used herein to refer to any numerical value may mean including numerical values within a range generally accepted in the art due to measurement limits or errors. For example, “about” may mean including values within a range of ±30%, ±20%, ±10%, or ±5% of any numerical value.

Herein, “a component B is directly arranged on a component A” may mean that a separate adhesive layer or adhesive member is not arranged between the component A and the component B. In this case, the component B may be formed through a continuous process on a base surface provided by the component A after the component A is formed.

Herein, “A and B overlap each other” may mean that at least a portion of A and at least a portion of B are arranged overlapping each other in a plan view in a direction (e.g., the z-axis direction) when viewed from a plane (e.g., the xy plane) perpendicular to the direction.

When a certain embodiment may be implemented differently, a particular process order may be performed differently from the described order. For example, two processes described in succession may be performed substantially at the same time or may be performed in an order opposite to the described order.

Sizes of elements in the drawings may be exaggerated for convenience of description. In other words, because the sizes and shapes of components in the drawings are arbitrarily illustrated for convenience of description, the disclosure is not limited thereto.

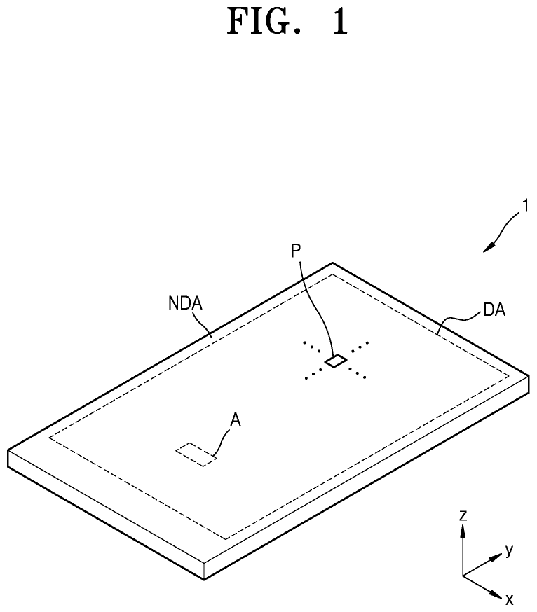

FIG. 1 is a perspective view schematically illustrating a display apparatus according to an embodiment.

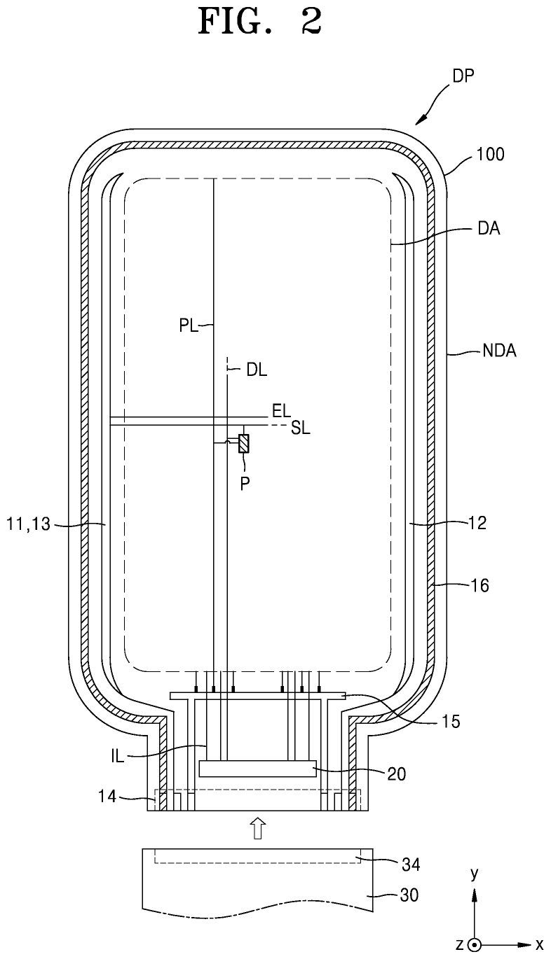

Referring to FIG. 1, a display panel included in a display apparatus 1 may include a display area DA and a non-display area NDA arranged outside the display area DA. Hereinafter, “the display panel includes a display area DA” may mean that a substrate 100 (see FIG. 2) included in the display panel includes the display area DA. Hereinafter, for convenience, it will be described that the substrate 100 includes the display area DA and the non-display area NDA.

The display area DA may display an image through pixels P arranged in the display area DA. The non-display area NDA may be an area arranged outside the display area DA and may not display an image, and may entirely surround the display area DA. A driver or the like for providing an electrical signal or power to the display area DA may be arranged in the non-display area NDA. A pad, which is an area to which an electronic device, a printed circuit board, or the like may be electrically connected, may be arranged in the non-display area NDA.

In an embodiment, FIG. 1 illustrates that the display area DA has a polygonal shape (e.g., a rectangular shape) in which the length in the x direction is less than the length in the y direction; however, the disclosure is not limited thereto. In another embodiment, the display area DA may have various shapes such as N-gonal shapes (where N is a natural number equal to or greater than 3), circular shapes, or elliptical shapes. FIG. 1 illustrates that the display area DA has a shape in which a corner portion thereof includes a vertex at which a straight line and another straight line meet each other; however, in another embodiment, the display area DA may have a polygonal shape with a rounded corner portion.

Hereinafter, for convenience of description, a case where the display apparatus 1 is an electronic apparatus such as a smart phone will be described below; however, the display apparatus 1 of the disclosure is not limited thereto. The display apparatus 1 may be applied to various products such as televisions, notebook computers, monitors, billboards, and Internet of Things (IoT) as well as portable electronic apparatuses such as mobile phones, smart phones, tablet personal computers (PCs), mobile communication terminals, electronic notebooks, electronic books, portable multimedia players (PMPs), navigation, and Ultra Mobile PCs (UMPCs). Also, the display apparatus 1 according to an embodiment may be applied to wearable devices such as smart watches, watch phones, glasses-type displays, and head-mounted displays (HMDs). Also, the display apparatus 1 according to an embodiment may be applied to a center information display (CID) arranged at a vehicle's instrument panel or a vehicle's center fascia or dashboard, a room mirror display replacing a vehicle's side mirror, or a display screen arranged at a rear side of a vehicle's front seat as entertainment for a vehicle's rear seat.

FIG. 2 is a plan view schematically illustrating a display panel included in a display apparatus according to an embodiment.

Referring to FIG. 2, a display panel DP may include a display area DA and a non-display area NDA outside the display area DA. The display area DA may be an area for displaying an image, and a plurality of pixels P may be arranged in the display area DA. FIG. 2 illustrates that the display area DA has a substantially rectangular shape with rounded corners; however, the disclosure is not limited thereto. As described above, the display area DA may have various shapes such as N-gonal shapes (where N is a natural number equal to or greater than 3), circular shapes, or elliptical shapes.

Each of the pixels P may refer to a subpixel and may include a display element such as an organic light emitting diode (OLED). Each pixel P may emit, for example, red, green, blue, or white light.

The non-display area NDA may be arranged outside the display area DA. Driving circuits for driving the pixels P and signal lines may be arranged in the non-display area NDA. For example, a first scan driving circuit 11, a second scan driving circuit 12, an emission control driving circuit 13, a terminal 14, a driving power supply line 15, and a common power supply line 16 may be arranged in the non-display area NDA.

The first scan driving circuit 11 and the second scan driving circuit 12 may provide scan signals to the pixels P through scan line SLs. The second scan driving circuit 12 may be arranged in parallel to the first scan driving circuit 11 with the display area DA disposed therebetween. Some of the pixels P arranged in the display area DA may be electrically connected to the first scan driving circuit 11, and the others may be connected to the second scan driving circuit 12. When necessary, the second scan driving circuit 12 may be omitted and all of the pixels P arranged in the display area DA may be electrically connected to the first scan driving circuit 11.

The emission control driving circuit 13 may be arranged on the side of the first scan driving circuit 11 and may provide emission control signals to the pixels P through emission control lines EL. FIG. 2 illustrates that the emission control driving circuit 13 is arranged only on one side of the display area DA; however, like the first scan driving circuit 11 and the second scan driving circuit 12, the emission control driving circuit 13 may be arranged on both sides of the display area DA.

A driving chip 20 may be arranged in the non-display area NDA. The driving chip 20 may include an integrated circuit for driving the display panel DP. The integrated circuit may be a data driving integrated circuit for generating data signals; however, the disclosure is not limited thereto.

The terminal 14 may be arranged in the non-display area NDA. The terminal 14 may be exposed, by not being covered by an insulating layer, and be electrically connected to a printed circuit board 30. A terminal 34 of the printed circuit board 30 may be electrically connected to the terminal 14 of the display panel DP.

The printed circuit board 30 may be configured to transmit power or control signals of a controller (not illustrated) to the display panel DP. Control signals generated by the controller may be transmitted to each of the driving circuits through the printed circuit board 30. Also, the controller may provide a driving voltage ELVDD to the driving power supply line 15 and may provide a common voltage ELVSS to the common power supply line 16. The driving voltage ELVDD may be transmitted to each pixel P through a driving voltage line PL connected to the driving power supply line 15, and the common voltage ELVSS may be transmitted to an opposite electrode of each pixel P. The driving power supply line 15 may have a shape extending in one direction (e.g., the x direction) on the lower side of the display area DA. The common power supply line 16 may have a loop shape with one side open and thus may have a shape partially surrounding the display area DA.

Moreover, the controller may generate data signals, and the generated data signals may be transmitted to input lines IL through the driving chip 20 and may be transmitted to the pixels P through data lines DL connected to the input lines IL. For reference, “line” may refer to “wiring.” This may also apply to the following embodiments and modifications thereof.

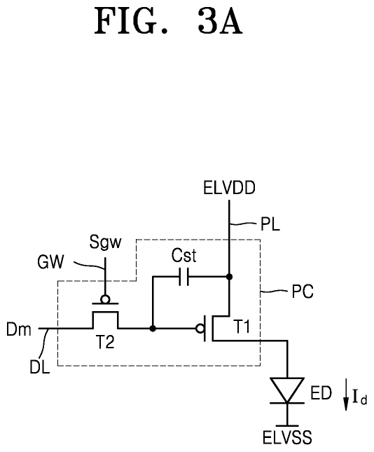

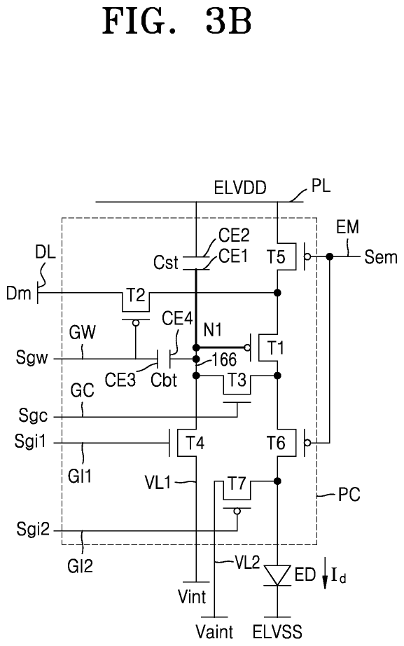

FIGS. 3A and 3B are equivalent circuit diagrams schematically illustrating a pixel included in a display apparatus according to embodiments.

Referring to FIG. 3A, a light emitting diode ED may be electrically connected to a pixel circuit PC, and the pixel circuit PC may include a first transistor T1, a second transistor T2, and a storage capacitor Cst.

The second transistor T2 may be configured to transmit a data signal Dm input through a data line DL to the first transistor T1 in response to a scan signal Sgw input through a scan line GW.

The storage capacitor Cst may be connected between the second transistor T2 and a driving voltage line PL and may store a voltage corresponding to the difference between a voltage received from the second transistor T2 and a driving voltage ELVDD supplied from the driving voltage line PL.

The first transistor T1 may be connected between the driving voltage line PL and the light emitting diode ED and may control a driving current I_{d} flowing from the driving voltage line PL through the light emitting diode ED in response to a voltage value stored in the storage capacitor Cst. An opposite electrode (e.g., a cathode) of the light emitting diode ED may be supplied with a common voltage ELVSS. The light emitting diode ED may emit light with a certain brightness according to the driving current I_{d}.

FIG. 3A illustrates a case where the pixel circuit PC includes two transistors and one storage capacitor; however, the disclosure is not limited thereto.

Referring to FIG. 3B, a pixel circuit PC may include seven transistors and two capacitors. The pixel circuit PC may include first to seventh transistors T1, T2, T3, T4, T5, T6, and T7, a storage capacitor Cst, and a boost capacitor Cbt. In another embodiment, the pixel circuit PC may not include the boost capacitor Cbt.

Some of the first to seventh transistors T1, T2, T3, T4, T5, T6, and T7 may be n-channel MOSFETs (NMOSs), and the others may be p-channel MOSFETs (PMOSs). For example, as illustrated in FIG. 3B, the third and fourth transistors T3 and T4 may be NMOSs, and the others may be PMOSs.

The first to seventh transistors T1, T2, T3, T4, T5, T6, and T7, the storage capacitor Cst, and the boost capacitor Cbt may be connected to a signal line. The signal line may include a scan line GW, an emission control line EM, a compensation gate line GC, a first initialization gate line GI1, a second initialization gate line GI2, and a data line DL. The pixel circuit PC may be electrically connected to a voltage line, for example, a driving voltage line PL, a first initialization voltage line VL1, a second initialization voltage line VL2, and a common power supply line 16 which supplies a common voltage ELVSS.

The first transistor T1 may be a driving transistor. A first gate electrode of the first transistor T1 may be connected to the storage capacitor Cst, a first electrode of the first transistor T1 may be electrically connected to the driving voltage line PL via the fifth transistor T5, and a second electrode of the first transistor T1 may be electrically connected to a pixel electrode (e.g., an anode) of the light emitting diode ED via the sixth transistor T6. One of the first electrode and the second electrode of the first transistor T1 may be a source electrode and the other may be a drain electrode. The first transistor T1 may supply a driving current Id to the light emitting diode ED according to a voltage applied to the first gate electrode of the first transistor T1.

The second transistor T2 may be a switching transistor. A second gate electrode of the second transistor T2 may be connected to the scan line GW, a first electrode of the second transistor T2 may be connected to the data line DL, and a second electrode of the second transistor T2 may be electrically connected to the driving voltage line PL via the fifth transistor T5 while being connected to the first electrode of the first transistor T1. One of the first electrode and the second electrode of the second transistor T2 may be a source electrode and the other may be a drain electrode. The second transistor T2 may perform a switching operation of transmitting the data signal Dm received through the data line DL to the first electrode of the first transistor T1 by being turned on in response to the scan signal Sgw received through the scan line GW.

The third transistor T3 may be a compensation transistor for compensating for a threshold voltage of the first transistor T1. A third gate electrode of the third transistor T3 may be connected to the compensation gate line GC. A first electrode of the third transistor T3 may be connected to a lower electrode CE1 of the storage capacitor Cst and the first gate electrode of the first transistor T1 through a node connection line 166. The first electrode of the third transistor T3 may be connected to the fourth transistor T4. A second electrode of the third transistor T3 may be electrically connected to the pixel electrode (e.g., the anode) of the light emitting diode ED via the sixth transistor T6 while being connected to the second electrode of the first transistor T1. One of the first electrode and the second electrode of the third transistor T3 may be a source electrode and the other may be a drain electrode.

The third transistor T3 may be turned on in response to a compensation signal Sgc received through the compensation gate line GC to electrically connect the first gate electrode and the second electrode (e.g., the drain electrode) of the first transistor T1 to each other to diode-connect the first transistor T1.

The fourth transistor T4 may be a first initialization transistor for initializing the first gate electrode of the first transistor T1. A fourth gate electrode of the fourth transistor T4 may be connected to the first initialization gate line GI1. A first electrode of the fourth transistor T4 may be connected to the first initialization voltage line VL1. A second electrode of the fourth transistor T4 may be connected to the lower electrode CE1 of the storage capacitor Cst, the first electrode of the third transistor T3, and the first gate electrode of the first transistor T1. One of the first electrode and the second electrode of the fourth transistor T4 may be a source electrode and the other may be a drain electrode. The fourth transistor T4 may perform an initialization operation of initializing the voltage of the first gate electrode of the first transistor T1 by transmitting a first initialization voltage Vint to the first gate electrode of the first transistor T1 by being turned on in response to a first initialization signal Sgi1 received through the first initialization gate line GI1.

The fifth transistor T5 may be an operation control transistor. A fifth gate electrode of the fifth transistor T5 may be connected to the emission control line EM, a first electrode of the fifth transistor T5 may be connected to the driving voltage line PL, and a second electrode of the fifth transistor T5 may be connected to the first electrode of the first transistor T1 and the second electrode of the second transistor T2. One of the first electrode and the second electrode of the fifth transistor T5 may be a source electrode and the other may be a drain electrode.

The sixth transistor T6 may be an emission control transistor. A sixth gate electrode of the sixth transistor T6 may be connected to the emission control line EM, a first electrode of the sixth transistor T6 may be connected to the second electrode of the first transistor T1 and the second electrode of the third transistor T3, and a second electrode of the sixth transistor T6 may be electrically connected to a second electrode of the seventh transistor T7 and the pixel electrode (e.g., the anode) of the light emitting diode ED. One of the first electrode and the second electrode of the sixth transistor T6 may be a source electrode and the other may be a drain electrode.

The fifth transistor T5 and the sixth transistor T6 may be simultaneously turned on in response to an emission control signal Sem received through the emission control line EM to transmit the driving voltage ELVDD to the light emitting diode ED to allow the driving current Id to flow through the light emitting diode ED.

The seventh transistor T7 may be a second initialization transistor for initializing the pixel electrode (e.g., the anode) of the light emitting diode ED. A seventh gate electrode of the seventh transistor T7 may be connected to the second initialization gate line GI2. A first electrode of the seventh transistor T7 may be connected to the second initialization voltage line VL2. The second electrode of the seventh transistor T7 may be connected to the second electrode of the sixth transistor T6 and the pixel electrode (e.g., the anode) of the light emitting diode ED. The seventh transistor T7 may be turned on in response to a second initialization signal Sgi2 received through the second initialization gate line GI2 to transmit a second initialization voltage Vaint to the pixel electrode (e.g., the anode) of the light emitting diode ED to initialize the pixel electrode of the light emitting diode ED.

In an embodiment, the second initialization gate line GI2 may be a subsequent scan line. For example, the second initialization gate line GI2 connected to the seventh transistor T7 of the pixel circuit PC arranged in an i-th row (where “i” is a natural number) may correspond to a scan line of the pixel circuit PC arranged in an (i+1)th row. In another embodiment, the second initialization gate line GI2 may be an emission control line EM. For example, the emission control line EM may be electrically connected to the fifth to seventh transistors T5, T6, and T7.

The storage capacitor Cst may include a lower electrode CE1 and an upper electrode CE2. The lower electrode CE1 of the storage capacitor Cst may be connected to the first gate electrode of the first transistor T1, and the upper electrode CE2 of the storage capacitor Cst may be connected to the driving voltage line PL. The storage capacitor Cst may store the charge corresponding to the difference between the driving voltage ELVDD and the voltage of the first gate electrode of the first transistor T1.

The boost capacitor Cbt may include a third electrode CE3 and a fourth electrode CE4. The third electrode CE3 may be connected to the scan line GW and the second gate electrode of the second transistor T2, and the fourth electrode CE4 may be connected to a first node N1 to which the node connection line 166 and the first electrode of the third transistor T3 are connected. The boost capacitor Cbt may increase the voltage of a first node N1 when the scan signal Sgw supplied through the scan line GW is turned off, and the black gradation may be clearly expressed when the voltage of the first node N1 increases. In an embodiment, the boost capacitor Cbt may be omitted.

The first node N1 may be an area where the first gate electrode of the first transistor T1, the first electrode of the third transistor T3, the second electrode of the fourth transistor T4, and the fourth electrode CE4 of the boost capacitor Cbt are connected.

In an embodiment, FIG. 3B illustrates that the third and fourth transistors T3 and T4 are NMOSs and the first, second, and fifth to seventh transistors T1, T2, T5, T6, and T7 are PMOSs. The first transistor T1 directly affecting the brightness of a display apparatus displaying an image may be configured to include a semiconductor layer including polycrystalline silicon having high reliability, and accordingly, a high-resolution display apparatus may be implemented.

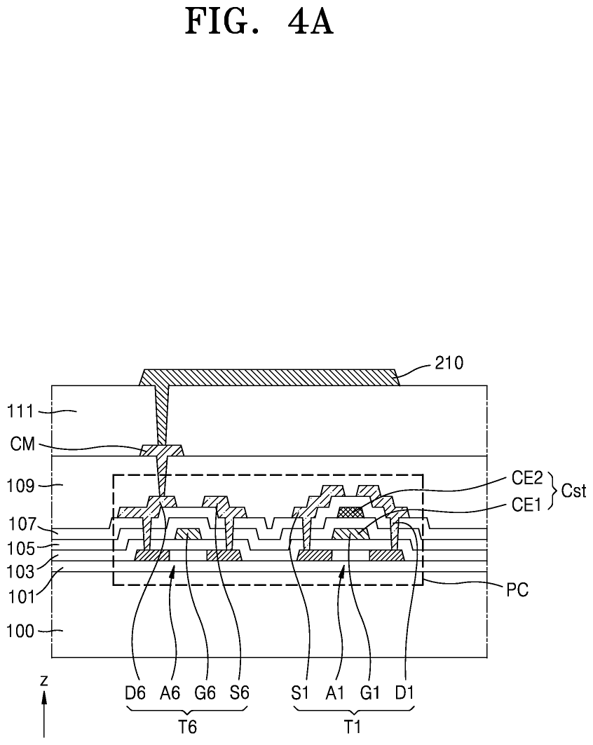

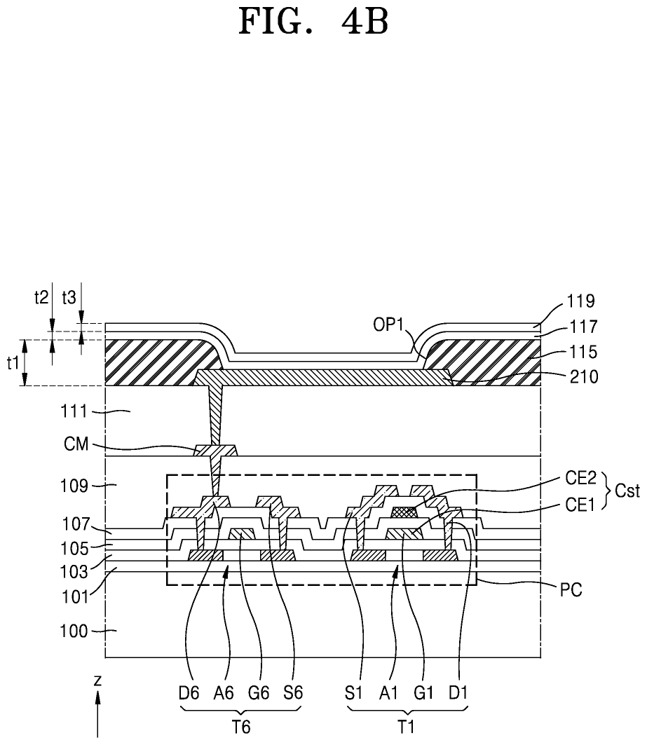

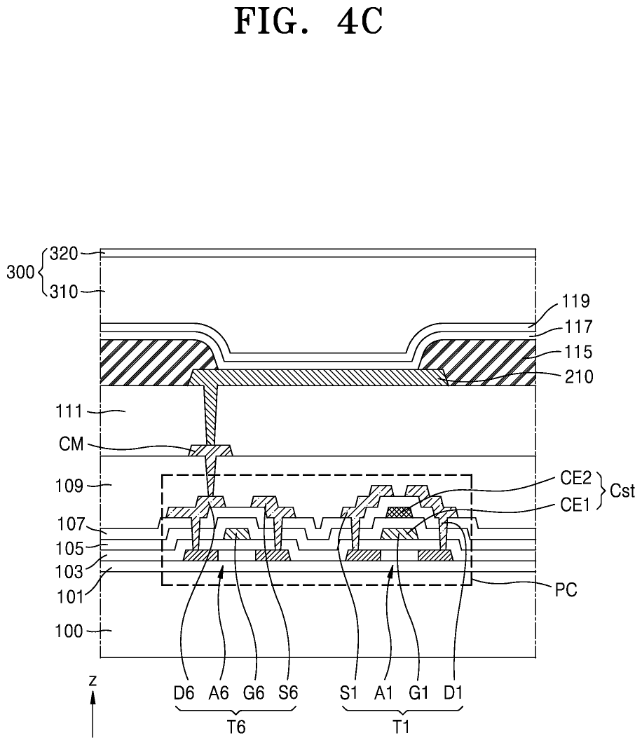

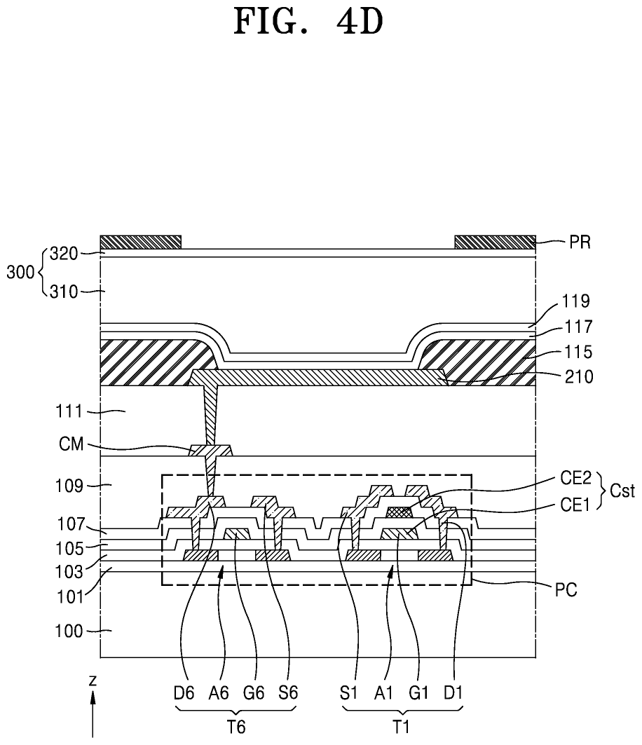

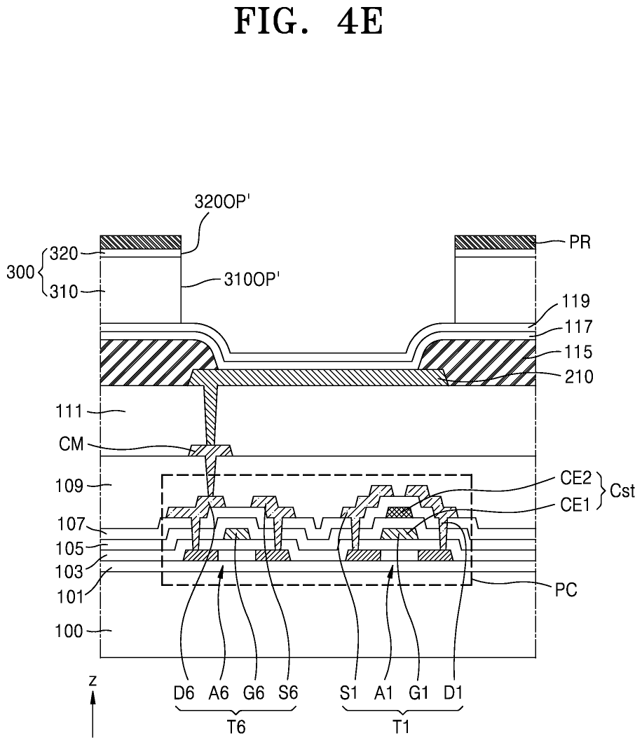

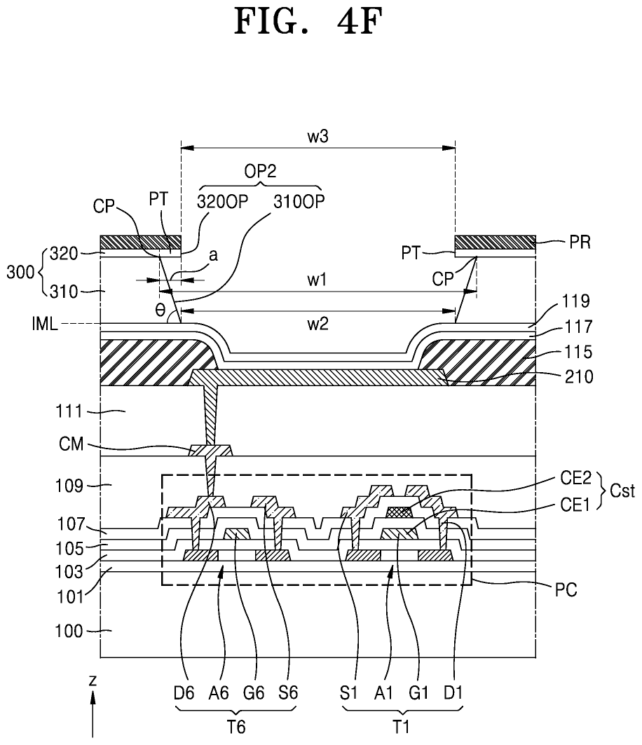

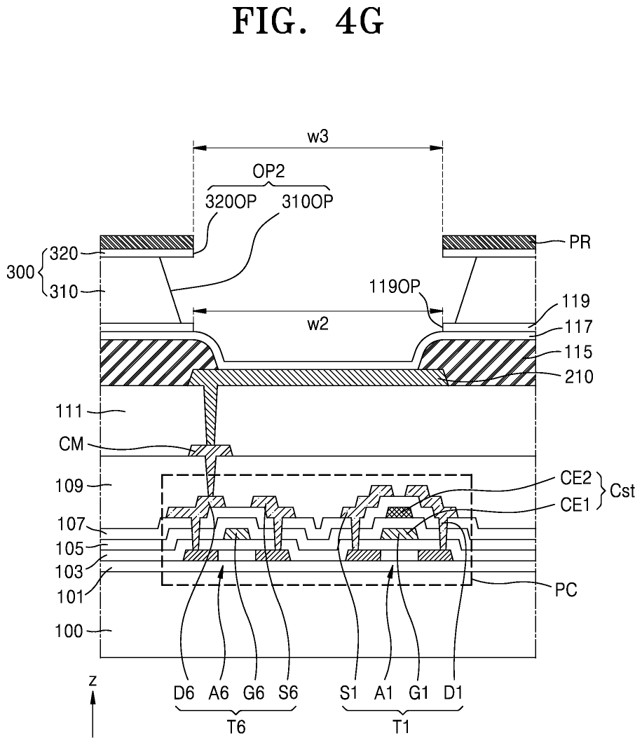

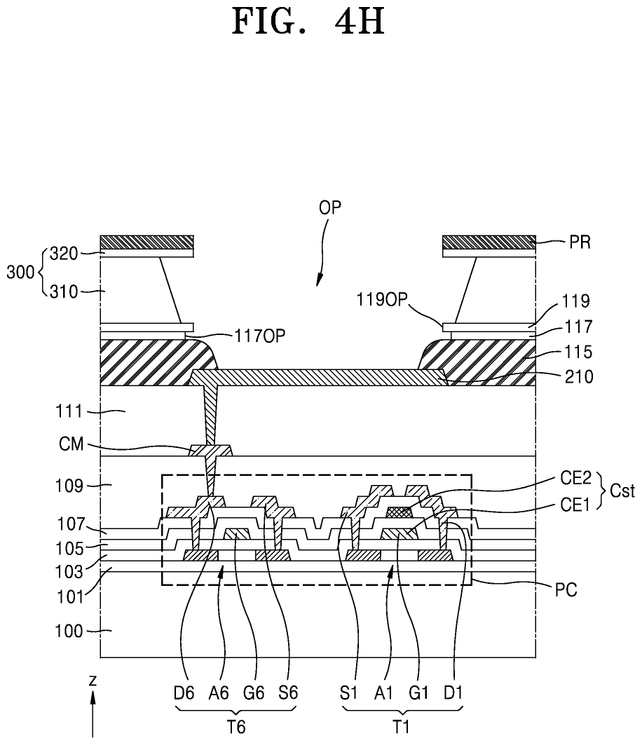

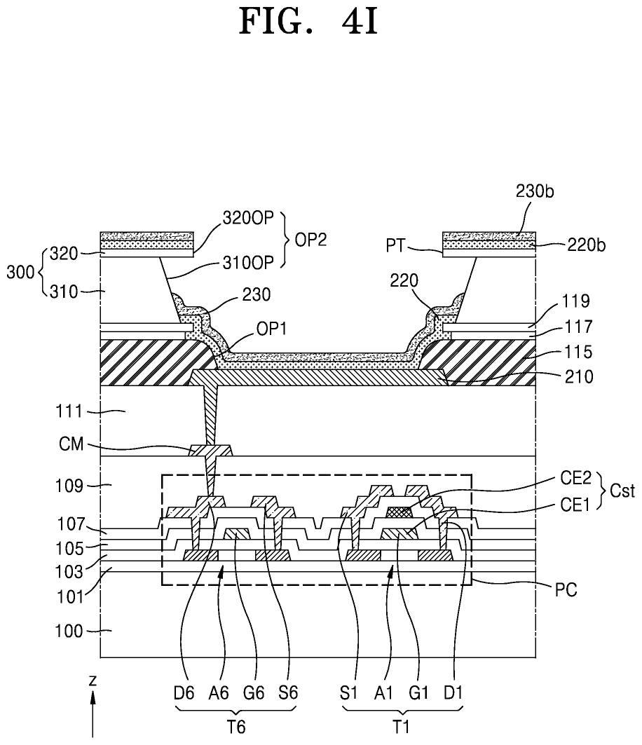

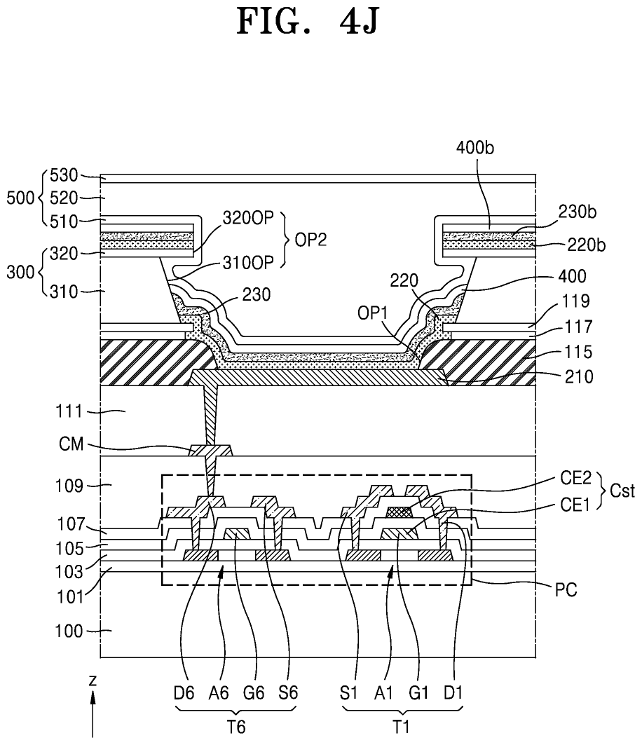

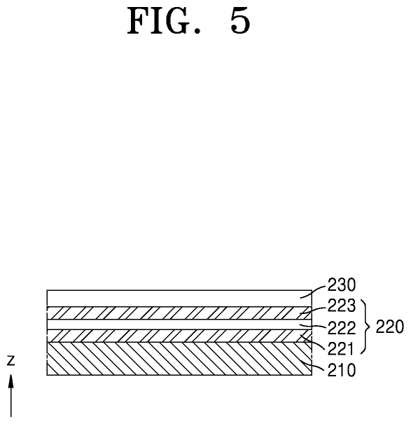

FIGS. 4A to 4J are cross-sectional views schematically illustrating some operations of a display apparatus manufacturing method according to an embodiment, and FIG. 5 is a cross-sectional view illustrating a stack structure of a light emitting diode according to an embodiment.

Referring to FIG. 4A, a pixel circuit PC may be formed over a substrate 100. The substrate 100 may include a glass material or a polymer resin. The substrate 100 may include a stack structure of an inorganic barrier layer and a base layer including a polymer resin. The polymer resin may include polyethersulfone, polyacrylate, polyetherimide, polyethylene naphthalate, polyethylene terephthalate, polyphenylene sulfide, polyarylate, polyimide, polycarbonate, cellulose triacetate, cellulose acetate propionate, or the like.

A buffer layer 101 may be arranged on the upper surface of the substrate 100. The buffer layer 101 may prevent impurities from penetrating into a semiconductor layer of a transistor. The buffer layer 101 may include an inorganic insulating material such as silicon nitride, silicon oxynitride, and silicon oxide and may include a single layer or multiple layers including the inorganic insulating material.

The pixel circuit PC may be disposed over the buffer layer 101. The pixel circuit PC may include a plurality of transistors and a storage capacitor as described above with reference to FIG. 3A or 3B. In an embodiment, FIG. 4A illustrates the first transistor T1, the sixth transistor T6, and the storage capacitor Cst of the pixel circuit PC described above with reference to FIG. 3B.

The first transistor T1 may include a first semiconductor layer A1 disposed over the buffer layer 101 and a first gate electrode G1 overlapping a channel area of the first semiconductor layer A1. The first semiconductor layer A1 may include a silicon-based semiconductor material, for example, polysilicon. The first semiconductor layer A1 may include a channel area and a first area and a second area arranged on both sides of the channel area. The first area and the second area may be areas including a higher concentration of impurities than the channel area, and one of the first area and the second area may correspond to a source area and the other may correspond to a drain area.

The sixth transistor T6 may include a sixth semiconductor layer A6 disposed over the buffer layer 101 and a sixth gate electrode G6 overlapping a channel area of the sixth semiconductor layer A6. The sixth semiconductor layer A6 may include a silicon-based semiconductor material, for example, polysilicon. The sixth semiconductor layer A6 may include a channel area and a first area and a second area arranged on both sides of the channel area. The first area and the second area may be areas including a higher concentration of impurities than the channel area, and one of the first area and the second area may correspond to a source area and the other may correspond to a drain area.

The first gate electrode G1 and the sixth gate electrode G6 may include a conductive material including molybdenum (Mo), aluminum (A1), copper (Cu), titanium (Ti), or the like and may include a single-layer or multiple-layer structure including the conductive material. A first gate insulating layer 103 for electrical insulation between the first gate electrode G1 and the first semiconductor layer A1 and between the sixth gate electrode G6 and the sixth semiconductor layer A6 may be arranged between the first gate electrode G1 and the first semiconductor layer A1 and between the sixth gate electrode G6 and the sixth semiconductor layer A6. The first gate insulating layer 103 may include an inorganic insulating material such as silicon nitride, silicon oxynitride, and silicon oxide and may include a single layer or multiple layers including the inorganic insulating material.

The storage capacitor Cst may include a lower electrode CE1 and an upper electrode CE2 overlapping each other in a plan view. In an embodiment, the lower electrode CE1 of the storage capacitor Cst may include the first gate electrode G1. In other words, the first gate electrode G1 may include the lower electrode CE1 of the storage capacitor Cst. For example, the first gate electrode G1 and the lower electrode CE1 of the storage capacitor Cst may be integrated with each other.

A first interlayer insulating layer 105 may be arranged between the lower electrode CE1 and the upper electrode CE2 of the storage capacitor Cst. The first interlayer insulating layer 105 may include an inorganic insulating material such as silicon oxide, silicon nitride, or silicon oxynitride and may include a single-layer or multiple-layer structure including the inorganic insulating material.

The upper electrode CE2 of the storage capacitor Cst may include a low-resistance conductive material such as molybdenum (Mo), aluminum (A1), copper (Cu), and/or titanium (Ti) and may include a single-layer or multiple-layer structure including the low-resistance conductive material.

A second interlayer insulating layer 107 may be disposed over the storage capacitor Cst. The second interlayer insulating layer 107 may include an inorganic insulating material such as silicon oxide, silicon nitride, or silicon oxynitride and may include a single-layer or multiple-layer structure including the inorganic insulating material.

A source electrode S1 and/or a drain electrode D1 electrically connected to the first semiconductor layer A1 of the first transistor T1 may be disposed over the second interlayer insulating layer 107. A source electrode S6 and/or a drain electrode D6 electrically connected to the sixth semiconductor layer A6 of the sixth transistor T6 may be disposed over the second interlayer insulating layer 107. The source electrodes S1 and S6 and/or the drain electrodes D1 and D6 may include a conductive material including molybdenum (Mo), aluminum (Al), copper (Cu), and/or titanium (Ti) and may include a single layer or multiple layers including the conductive material. In an embodiment, the source electrodes S1 and S6, the drain electrodes D1 and D6, and the data line DL may include a multilayer of Ti/Al/Ti. In an embodiment, some of the source electrodes S1 and S6 and/or the drain electrodes D1 and D6 may be omitted.

A first organic insulating layer 109 may be disposed over the pixel circuit PC. The first organic insulating layer 109 may include an organic insulating material such as a general-purpose polymer such as polymethylmethacrylate (PMMA) or polystyrene (PS), a polymer derivative having a phenolic group, an acrylic polymer, an imide-based polymer, an aryl ether-based polymer, an amide-based polymer, a fluorine-based polymers, a p-xylene-based polymer, a vinyl alcohol-based polymer, or any blend thereof.

A connection metal CM may be disposed over the first organic insulating layer 109. The connection metal CM may include molybdenum (Mo), aluminum (Al), copper (Cu), and/or titanium (Ti) and may include a single layer or multiple layers including the above material.

A second organic insulating layer 111 may be arranged between the connection metal CM and a pixel electrode 210. The second organic insulating layer 111 may include an organic insulating material such as a general-purpose polymer such as polymethylmethacrylate (PMMA) or polystyrene (PS), a polymer derivative having a phenolic group, an acrylic polymer, an imide-based polymer, an aryl ether-based polymer, an amide-based polymer, a fluorine-based polymers, a p-xylene-based polymer, a vinyl alcohol-based polymer, or any blend thereof. In an embodiment, the first organic insulating layer 109 and the second organic insulating layer 111 may include polyimide.

According to the embodiment described with reference to FIG. 4A, the pixel circuit PC and the pixel electrode 210 are electrically connected through the connection metal CM; however, according to another embodiment, the connection metal CM may be omitted and one organic insulating layer may be located between the pixel circuit PC and the pixel electrode 210.

Alternatively, three or more organic insulating layers may be located between the pixel circuit PC and the pixel electrode 210, and the pixel circuit PC and the pixel electrode 210 may be electrically connected through a plurality of connection metals.

The pixel electrode 210 may be formed over the second organic insulating layer 111. The pixel electrode 210 may be formed as a (semi)transparent electrode or as a reflective electrode. When the pixel electrode 210 is formed as a (semi)transparent electrode, it may be formed of indium tin oxide (ITO), indium zinc oxide (IZO), zinc oxide (ZnO), indium oxide (In₂O₃), indium gallium oxide (IGO), or aluminum zinc oxide (AZO). When the pixel electrode 210 is formed as a reflective electrode, a reflective layer may be formed of silver (Ag), magnesium (Mg), aluminum (Al), platinum (Pt), palladium (Pd), gold (Au), nickel (Ni), neodymium (Nd), iridium (Ir), chromium (Cr), or any compound thereof and then a layer including ITO, IZO, ZnO, or In₂O₃ may be formed over the reflective layer. In an embodiment, the pixel electrode 210 may have a structure in which an ITO layer, an Ag layer, and an ITO layer are sequentially stacked. The pixel electrode 210 may be electrically connected to the connection metal CM through a contact hole formed through the second organic insulating layer 111.

Referring to FIG. 4B, a pixel definition layer 115 may be disposed over the second organic insulating layer 111. In this case, the pixel electrode 210 may be arranged between the second organic insulating layer 111 and the pixel definition layer 115. The pixel definition layer 115 may define a light emitting area by including a first opening OP1 corresponding to each pixel, that is, a first opening OP1 through which at least a center portion of the pixel electrode 210 is exposed. In an embodiment, the pixel definition layer 115 may be entirely formed over the substrate 100 and then patterned to form a first opening OP1 exposing the pixel electrode 210. The pixel definition layer 115 may cover the side surface of the pixel electrode 210.

The pixel definition layer 115 may include an organic insulating material. The pixel definition layer 115 may include at least one organic insulating material selected from among polyimide, polyamide, acrylic resin, benzocyclobutene, and phenol resin.

A first pixel protection layer 117 may be formed over the pixel definition layer 115. The first pixel protection layer 117 may be entirely formed over the substrate 100. The first pixel protection layer 117 may be formed to cover the first opening OP1 of the pixel definition layer 115. That is, the first pixel protection layer 117 may be formed over the pixel definition layer 115 and the pixel electrode 210. The first pixel protection layer 117 may prevent the pixel electrode 210 from being damaged by gas or liquid materials used in various etching processes or ashing processes included in the display apparatus manufacturing process. The first pixel protection layer 117 may include a conductive oxide such as indium tin oxide (ITO), indium zinc oxide (IZO), indium gallium zinc oxide (IGZO), indium tin zinc oxide (ITZO), zinc oxide (ZnO), aluminum-doped zinc oxide (AZO), gallium-doped zinc oxide (GZO), zinc tin oxide (ZTO), gallium tin oxide (GTO), and fluorine-doped tin oxide (FTO). In an embodiment, a thickness t2 of the first pixel protection layer 117 may be less than a thickness t1 of the pixel definition layer 115. For example, the thickness t1 of the pixel definition layer 115 may be about 1,000 angstroms (A), and the thickness t2 of the first pixel protection layer 117 may be about 500 angstroms.

A second pixel protection layer 119 may be formed over the first pixel protection layer 117. The second pixel protection layer 119 may be entirely formed over the substrate 100. The second pixel protection layer 119 may protect the first pixel protection layer 117. Particularly, the second pixel protection layer 119 may prevent or minimize the pixel electrode 210 under the first pixel protection layer 117 from being damaged during a subsequent etching process. The second pixel protection layer 119 may include a material having good etching selectivity to the first pixel protection layer 117 during etching the second pixel protection layer 119. That is, the second pixel protection layer 119 may include a material having a greater etching rate than an etching rate of the first pixel protection layer 117 to an etchant etching the second pixel protection layer 119. For example, the second pixel protection layer 119 may include at least one of silicon oxide, silicon nitride, and silicon oxynitride. When the second pixel protection layer 119 is formed too thick, the process efficiency may degrade. On the other hand, when the second pixel protection layer 119 is formed too thin, the first pixel protection layer 117 may not be properly protected from etching. A thickness t3 of the second pixel protection layer 119 may be about 900 angstroms or less. In an embodiment, the thickness t3 of the second pixel protection layer 119 may be about 100 angstroms to about 900 angstroms, about 300 angstroms to about 600 angstroms, or about 300 angstroms to about 500 angstroms. In an embodiment, the thickness t3 of the second pixel protection layer 119 may be about 500 angstroms. In an embodiment, the thickness t3 of the second pixel protection layer 119 may be less than the thickness t1 of the pixel definition layer 115. For example, the thickness t1 of the pixel definition layer 115 may be about 1,000 angstroms, and the thickness t3 of the second pixel protection layer 119 may be about 500 angstroms. However, the disclosure is not limited thereto.

Referring to FIG. 4C, a bank layer 300 may be formed over the second pixel protection layer 119. The bank layer 300 may be entirely formed over the substrate 100. The first pixel protection layer 117 and the second pixel protection layer 119 may be arranged between the pixel definition layer 115 and the bank layer 300. The bank layer 300 may include a first subbank layer 310 and a second subbank layer 320 disposed over the first subbank layer 310. FIG. 4C illustrates that the bank layer 300 includes only the first subbank layer 310 and the second subbank layer 320 disposed over the first subbank layer 310; however, the disclosure is not limited thereto. In another embodiment, the bank layer 300 may include a first subbank layer 310, a second subbank layer 320 disposed over the first subbank layer 310, and a third subbank layer disposed under the first subbank layer 310, and the third subbank layer may include the same material as or a different material than the second subbank layer 320. In another embodiment, the bank layer 300 may not include the first subbank layer 310 and the second subbank layer 320 but may include a single layer.

The first subbank layer 310 and the second subbank layer 320 may include different metals. For example, the first subbank layer 310 and the second subbank layer 320 may include metals with different etch rates to an etchant etching the second subbank layer 320. In an embodiment, the first subbank layer 310 may be a layer including aluminum (Al) and the second subbank layer 320 may be a layer including titanium (Ti).

The thickness of the first subbank layer 310 may be greater than the thickness of the second subbank layer 320. In other words, the thickness of the second subbank layer 320 may be less than the thickness of the first subbank layer 310. In an embodiment, the thickness of the first subbank layer 310 may be greater than about 5 times the thickness of the second subbank layer 320. In another embodiment, the thickness of the first subbank layer 310 may be greater than about 6 times, greater than about 7 times, or greater than about 8 times the thickness of the second subbank layer 320. In an embodiment, the thickness of the first subbank layer 310 may be about 4,000 angstroms to about 8,000 angstroms and the thickness of the second subbank layer 320 may be about 500 angstroms to about 800 angstroms. The thickness of the first subbank layer 310 may be about 4 times or more, about 5 times or more, or about 6 times or more than the thickness of the pixel definition layer 115.

In an embodiment, the bank layer 300 and the pixel definition layer 115 may extend from the display area DA (see FIG. 2) to the non-display area NDA (see FIG. 2) and overlap the common power supply line 16 (see FIG. 2). In this case, the pixel definition layer 115 may include an opening portion overlapping the common power supply line 16 and exposing a portion of the upper surface of the common power supply line 16. The first subbank layer 310 of the bank layer 300 may directly contact the common power supply line 16 through the opening portion of the pixel definition layer 115. In other words, the first subbank layer 310 may be electrically connected to the common power supply line 16.

Referring to FIG. 4D, a photoresist PR may be formed over the bank layer 300. The photoresist PR may include an opening in an area corresponding to the pixel electrode 210 and the first opening OP1 in the pixel definition layer 115. A portion of the upper surface of the bank layer 300 may be exposed through the opening of the photoresist PR.

Referring to FIG. 4E, a portion of the bank layer 300, for example, a portion of the second subbank layer 320 and a portion of the first subbank layer 310, may be removed by using the photoresist PR as a mask. For example, a portion of the second subbank layer 320 and a portion of the first subbank layer 310 may be sequentially removed through the opening of the photoresist PR.

Through an etching process, a first’ subopening 310OP′ may be formed in the first subbank layer 310 and a second’ subopening 320OP′ may be formed in the second subbank layer 320 in an area corresponding to the pixel electrode 210 and the first opening OP1 in the pixel definition layer 115.

A portion of the second subbank layer 320 and a portion of the first subbank layer 310 may be removed by dry etching. During the etching process, the first pixel protection layer 117 and the second pixel protection layer 119 may protect the pixel electrode 210 disposed thereunder from etching. During the etching process, the second pixel protection layer 119 may protect the first pixel protection layer 117. Because the bank layer 300 and the second pixel protection layer 119 may have a good etching selectivity to an etchant etching the bank layer 300, the second pixel protection layer 119 may hardly be etched by the etchant etching the bank layer 300.

Referring to FIG. 4F, a second opening OP2 may be formed by removing a portion of the bank layer 300.

The side surfaces of the second subbank layer 320 and the first subbank layer 310 may be etched through the first subopening 310OP′ and the second’ subopening 320OP′ illustrated in FIG. 4E. A first subopening 310OP having a greater width than the first’ subopening 310OP′ of the first subbank layer 310 may be formed in the first subbank layer 310. A second subopening 320OP having a width greater than or equal to the width of the second’ subopening 320OP′ of the second subbank layer 320 may be formed in the second subbank layer 320. The second opening OP2 may include the first subopening 310OP and the second subopening 320OP.

In an embodiment, the first subopening 310OP of the first subbank layer 310 may have a shape in which the width thereof decreases toward the lower portion thereof (the portion close to the substrate 100). For example, a first width w1 that is the width of the first subopening 310OP at the interface between the first subbank layer 310 and the second subbank layer 320 may be greater than a second width w2 that is the width of the first subopening 310OP at the interface between the first subbank layer 310 and the second pixel protection layer 119. In other words, the side surface of the first subbank layer 310 defining the first subopening 310OP may include a forward-tapered inclined surface.

In the process of forming the second opening OP2 in the bank layer 300, the first subbank layer 310 may be removed more than the second subbank layer 320. In other words, in the process of forming the second opening OP2 in the bank layer 300, the second subbank layer 320 may be removed less than the first subbank layer 310. In this case, the second subbank layer 320 may not be etched or may be etched little.

In an embodiment, the second opening OP2 may be formed by wet etching. For example, the first subopening 310OP of the first subbank layer 310 may be formed by wet etching. As described above, the first subbank layer 310 and the second subbank layer 320 may include metals with different etch rates. In a wet etching process, the etch rate of the first subbank layer 310 may be higher than the etch rate of the second subbank layer 320. Thus, the second subbank layer 320 may not be etched or etched little during the wet etching or may be less etched than the first subbank layer 310. As a result, the first width w1 of the first subopening 310OP may be greater than a third width w3 that is the width of the second subopening 320OP.

The material included in the first pixel protection layer 117 may be etched by an etchant used in an etching process for forming the first subopening 310OP of the first subbank layer 310. When the first pixel protection layer 117 is etched, the pixel electrode 210 disposed thereunder may be damaged. Thus, the second pixel protection layer 119 may be disposed over the first pixel protection layer 117 to protect the first pixel protection layer 117 during the etching process for forming the first subopening 310OP of the first subbank layer 310. During the etching process for forming the first subopening 310OP of the first subbank layer 310, the first pixel protection layer 117 and the second pixel protection layer 119 may protect the pixel electrode 210 disposed under the first pixel protection layer 117 and the second pixel protection layer 119.

Because the first subopening 310OP of the first subbank layer 310 has a greater diameter than the second subopening 320OP of the second subbank layer 320, the second subbank layer 320 may include a tip PT.

A portion of the second subbank layer 320 defining the second subopening 320OP of the second subbank layer 320 may protrude toward the center of the second subopening 320OP from a point CP where the side surface of the first subbank layer 310 facing the first subopening 310OP of the first subbank layer 310 and the bottom surface of the second subbank layer 320 meet each other. As a result, the bank layer 300 may have an undercut structure. In this case, a portion of the second subbank layer 320 protruding toward the center of the second subopening 320OP may be defined as a tip PT. The length of the tip PT, for example, a length “a” from the point CP to the edge (or the side surface) of the tip PT, may be about 2 μm or less. In an embodiment, the length of the tip PT of the second subbank layer 320 may be about 0.3 μm to about 1 μm or about 0.3 μm to about 0.7 μm.

An inclination angle θ of the forward-tapered side surface of the first subbank layer 310 (e.g., the smaller angle among the inclination angles of the side surface of the first subbank layer 310 with respect to an imaginary line IML parallel to the upper surface of the substrate 100) may be about 60° to about 90°.

Referring to FIG. 4G, a portion of the second pixel protection layer 119 may be removed by using the photoresist PR as a mask. A portion of the second pixel protection layer 119 may be removed by dry etching. The width of an opening 119OP of the second pixel protection layer 119 may be substantially equal to the width of the opening of the photoresist PR and/or the upper width of the second opening OP2 of the bank layer 300 (e.g., the third width w3 of the second subopening 320OP of the second subbank layer 320). In an embodiment, the width of the opening 119OP of the second pixel protection layer 119 may be less than the second width w2 of the first subopening 310OP at the interface between the first subbank layer 310 and the second pixel protection layer 119.

Referring to FIG. 4H, a portion of the first pixel protection layer 117 may be removed by using the photoresist PR as a mask. A portion of the first pixel protection layer 117 may be removed by wet etching. In this case, a portion of the first pixel protection layer 117 may be removed by using a material capable of selectively etching the first pixel protection layer 117 among the first pixel protection layer 117 and the pixel electrode 210.

An opening 117OP may be formed by removing a portion of the first pixel protection layer 117, and the pixel electrode 210 may be exposed through the opening 117OP of the first pixel protection layer 117. In other words, the first pixel protection layer 117 and the second pixel protection layer 119 may be arranged only between the bank layer 300 and the pixel definition layer 115. The width of the opening 117OP formed by removing a portion of the first pixel protection layer 117 may be different from the width of the opening 119OP of the second pixel protection layer 119. FIG. 4H illustrates that the width of the opening 117OP is greater than the width of the opening 119OP, however, the disclosure is not limited thereto. In an embodiment, the width of the opening 117OP of the first pixel protection layer 117 may be less than the width of the opening 119OP of the second pixel protection layer 119. Thereafter, the photoresist PR may be removed.

In the process of FIG. 4H, the pixel definition layer 115 may include moisture. Thus, a process of removing the moisture in the pixel definition layer 115 may be additionally performed.

In this case, the moisture in the pixel definition layer 115 may be removed using a vacuum oven.

Referring to FIG. 4I, an intermediate layer 220 may be formed over the pixel electrode 210 through the first opening OP1 and the second opening OP2, and an opposite electrode 230 may be formed over the intermediate layer 220 through the first opening OP1 and the second opening OP2.

The intermediate layer 220 may include an emission layer 222 as illustrated in FIG. 5. The intermediate layer 220 may include a functional layer arranged between the pixel electrode 210 and the emission layer 222 and/or between the emission layer 222 and the opposite electrode 230. Hereinafter, a common layer arranged between the pixel electrode 210 and the emission layer 222 will be referred to as a first common layer 221, and a common layer arranged between the emission layer 222 and the opposite electrode 230 will be referred to as a second common layer 223 as illustrated in FIG. 5. The first common layer 221 or the second common layer 223 may be omitted.

The emission layer 222 may include a high-molecular weight or low-molecular weight organic material for emitting light of a certain color (red, green, or blue). In another embodiment, the emission layer 222 may include an inorganic material or quantum dots.

The first common layer 221 may include a hole transport layer (HTL) and/or a hole injection layer (HIL). The second common layer 223 may include an electron transport layer (ETL) and/or an electron injection layer (EIL). The first common layer 221 and the second common layer 223 may include an organic material.

The intermediate layer 220 may have a single-stack structure including a single emission layer or may have a tandem structure that is a multi-stack structure including a plurality of emission layers. In the case of having a tandem structure, a charge generation layer (CGL) may be arranged between adjacent stacks.

The opposite electrode 230 may include a conductive material having a low work function. For example, the opposite electrode 230 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or any alloy thereof. Alternatively, the opposite electrode 230 may further include a layer such as ITO, IZO, ZnO, or In₂O₃ over the (semi)transparent layer including the above material.

Referring back to FIG. 4I, the intermediate layer 220 may be arranged overlapping the pixel electrode 210 through the first opening OP1 of the pixel definition layer 115 and the second opening OP2 of the bank layer 300. The intermediate layer 220 may contact the pixel electrode 210.

The opposite electrode 230 may be disposed over the intermediate layer 220. The opposite electrode 230 may be electrically connected to the first subbank layer 310. In an embodiment, the edge or outer portion (or peripheral portion) of the opposite electrode 230 may cover the edge or outer portion (or peripheral portion) of the intermediate layer 220 and may directly contact the side surface of the first subbank layer 310. Herein, “the outer portion (or peripheral portion) of the opposite electrode 230” may refer to “a portion of the opposite electrode 230 including the edge of the opposite electrode 230.”

The intermediate layer 220 and the opposite electrode 230 may be deposited without using a separate mask. Thus, a deposition material for forming the intermediate layer 220 and a deposition material for forming the opposite electrode 230 may form a dummy intermediate layer 220b and a dummy opposite electrode 230b over the bank layer 300. The intermediate layer 220 and the dummy intermediate layer 220b may be separated and spaced apart from each other by the tip PT, and the opposite electrode 230 and the dummy opposite electrode 230b may be separated and spaced apart from each other by the tip PT. The intermediate layer 220 and the dummy intermediate layer 220b may include the same material and/or the same number of sublayers (e.g., a first common layer, an emission layer, and a second common layer). The opposite electrode 230 and the dummy opposite electrode 230b may include the same material.

Referring to FIG. 4J, a capping layer 400 and an encapsulation layer 500 may be formed over a light emitting diode ED.

The capping layer 400 may be formed over the opposite electrode 230. In an embodiment, the capping layer 400 may be arranged between the opposite electrode 230 and a first inorganic encapsulation layer 510 described below. When the capping layer 400 is formed, a dummy capping layer 400b may be formed together over the dummy opposite electrode 230b. In an embodiment, the dummy capping layer 400b may be arranged between the dummy opposite electrode 230b and the first inorganic encapsulation layer 510 described below. In an embodiment, the capping layer 400 may be omitted.

The capping layer 400 may protect the opposite electrode 230 and simultaneously improve the external light emission efficiency of the light emitting diode ED by causing constructive interference.

The capping layer 400 may be an organic capping layer including an organic material, an inorganic capping layer including an inorganic material, or a composite capping layer including an organic material and an inorganic material.

The encapsulation layer 500 may include at least one inorganic encapsulation layer and at least one organic encapsulation layer. FIG. 4J illustrates that the encapsulation layer 500 includes a first inorganic encapsulation layer 510, an organic encapsulation layer 520 disposed over the first inorganic encapsulation layer 510, and a second inorganic encapsulation layer 530 disposed over the organic encapsulation layer 520, however, the disclosure is not limited thereto.

The first inorganic encapsulation layer 510 may have relatively excellent step coverage. Thus, the first inorganic encapsulation layer 510 may cover at least a portion of the inner surface of the second opening OP2 of the bank layer 300 having an undercut structure. In an embodiment, the first inorganic encapsulation layer 510 may be continuously formed to overlap (or cover) the upper surface and side surface of the dummy capping layer 400b, the side surface of the dummy opposite electrode 230b, the side surface of the dummy intermediate layer 220b, the side surface and bottom surface of the second subbank layer 320, the side surface of the first subbank layer 310, and the upper surface of the capping layer 400. In an embodiment where the capping layer 400 is omitted, the first inorganic encapsulation layer 510 may be continuously formed to overlap (or cover) the upper surface and side surface of the dummy opposite electrode 230b, the side surface of the dummy intermediate layer 220b, the side surface and bottom surface of the second subbank layer 320, the side surface of the first subbank layer 310, and the upper surface of the opposite electrode 230. The first inorganic encapsulation layer 510 formed as described above may reduce or block the penetration path of impurities such as moisture and/or air.

The organic encapsulation layer 520 may be formed over the first inorganic encapsulation layer 510. The organic encapsulation layer 520 may fill at least a portion or all of the first opening OP1 of the pixel definition layer 115 and the second opening OP2 of the bank layer 300 to provide a flat base surface to the components arranged over the organic encapsulation layer 520.

In an embodiment, the organic encapsulation layer 520 may be entirely formed over the substrate 100. In this case, the organic encapsulation layer 520 filling a plurality of openings may be integrally formed and may provide a flatter base surface.

The second inorganic encapsulation layer 530 may be formed over the organic encapsulation layer 520. The second inorganic encapsulation layer 530 may include one or more inorganic materials among aluminum oxide, titanium oxide, tantalum oxide, hafnium oxide, zinc oxide, silicon oxide, silicon nitride, and silicon oxynitride. The second inorganic encapsulation layer 530 may include a single layer or multiple layers including the above material.

The second inorganic encapsulation layer 530 may prevent damage to the organic encapsulation layer 520 in a subsequent process and provide a flat base surface to the components located over the second inorganic encapsulation layer 530.

FIGS. 4A to 4J illustrate that the side surface of the first subbank layer 310 includes a forward-tapered inclined surface. However, the disclosure is not limited thereto.

FIG. 6 is a cross-sectional view schematically illustrating a display apparatus according to an embodiment.

Referring to FIG. 6, also in the display apparatus according to an embodiment, as described with reference to FIGS. 4A to 4J, the pixel definition layer 115 may be disposed over the second organic insulating layer 111, and the bank layer 300 may be disposed over the pixel definition layer 115. The first pixel protection layer 117 and the second pixel protection layer 119 may be arranged between the pixel definition layer 115 and the bank layer 300.

Referring to FIG. 6, the bank layer 300 according to an embodiment may include a first subbank layer 310 and a second subbank layer 320 disposed over the first subbank layer 310, and the first subbank layer 310 and the second subbank layer 320 may include different metals. For example, the first subbank layer 310 and the second subbank layer 320 may include metals with different etch rates. The thickness of the first subbank layer 310 may be greater than the thickness of the second subbank layer 320. In other words, the thickness of the second subbank layer 320 may be less than the thickness of the first subbank layer 310. The bank layer 300 may form a second opening OP2 having an undercut shape.

In this case, a first subopening 310OP included in the first subbank layer 310 may have a shape in which the width thereof increases toward the lower portion thereof. In other words, a first width w1 of the first subopening 310OP at the interface between the first subbank layer 310 and the second subbank layer 320 may be less than a second width w2 of the first subopening 310OP at the interface between the first subbank layer 310 and the second pixel protection layer 119. That is, the side surface of the first subbank layer 310 defining an opening of the first subbank layer 310 may include a reverse-tapered inclined surface.

In the process of forming the second opening OP2 in the bank layer 300, the first subbank layer 310 may be removed more than the second subbank layer 320. In other words, in the process of forming the second opening OP2 in the bank layer 300, in an embodiment, the second subbank layer 320 may be removed less than the first subbank layer 310. As a result, the second opening OP2 may have an undercut shape. In this case, the second subbank layer 320 may not be etched or may be etched little. Thus, a portion of the second subbank layer 320 may form a tip PT protruding toward the center of the first subopening 310OP from the point where the side surface of the first subbank layer 310 defining the first subopening 310OP of the first subbank layer 310 and the bottom surface of 320 of the second subbank layer 320 meet each other.

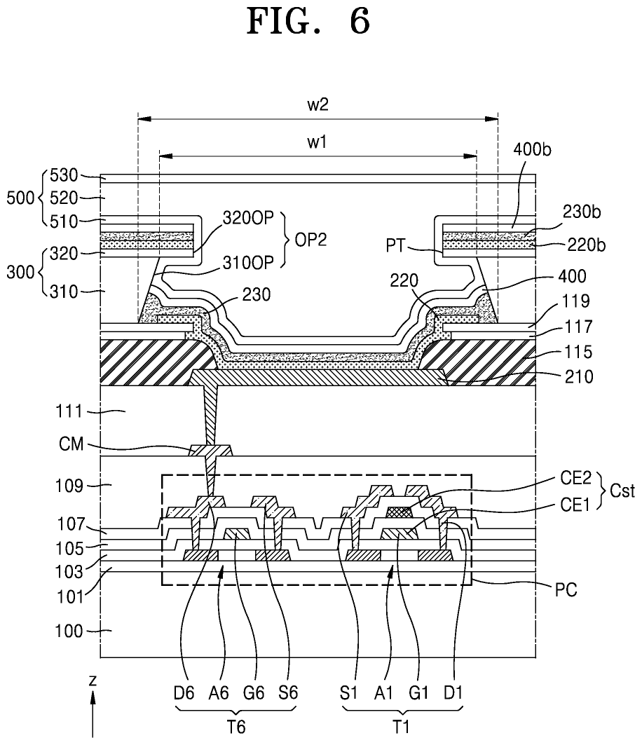

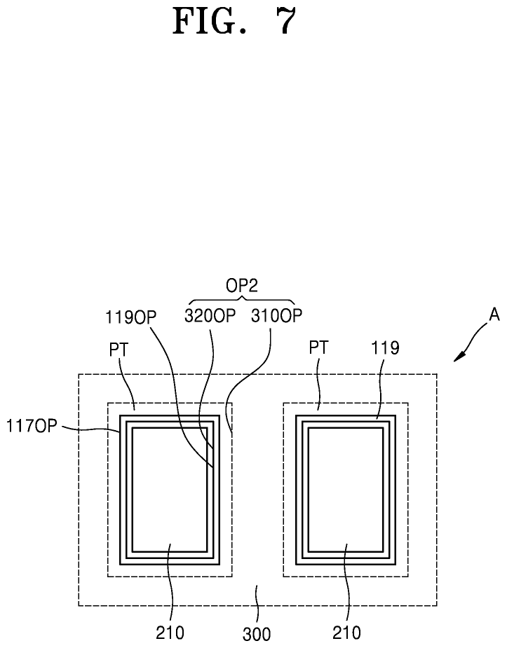

FIG. 7 is a plan view schematically illustrating a display apparatus according to an embodiment. Particularly, FIG. 7 is a plan view of a region A of the display apparatus of FIG. 1.

Referring to FIG. 7, a plurality of pixel electrodes 210 may be arranged adjacent to each other. As described above, a bank layer 300 may be entirely formed over the substrate 100 (see FIG. 2) and then a portion of the bank layer 300 may be etched and removed by using the photoresist PR (see FIG. 4E) as a mask. The bank layer 300 may form a second opening OP2 overlapping the pixel electrode 210, and the second subbank layer 320 (see FIG. 6) included in the bank layer 300 may include a tip PT protruding toward the center of the pixel electrode 210.

Because the bank layer 300 is formed in the same way as above, the tip PT may be formed to surround the pixel electrode 210 when viewed in an approximately vertical direction from the substrate 100.

Because the tip PT of the bank layer 300 is formed to surround the pixel electrode 210, when the opposite electrode 230 is formed as described with reference to FIG. 4I, the dummy opposite electrode 230b located over the tip PT and the opposite electrode 230 located overlapping the pixel electrode 210 may be spaced apart from each other by the tip PT. Likewise, because the tip PT of the bank layer 300 is formed to surround the pixel electrode 210, when the intermediate layer 220 is formed, the dummy intermediate layer 220b located over the tip PT and the intermediate layer 220 located overlapping the pixel electrode 210 may be spaced apart from each other by the tip PT. In this case, the bank layer 300 having an undercut shape may be regarded as functioning as a separator.

As described above, the second pixel protection layer 119 may also be entirely formed over the substrate 100 and then partially etched and removed. The opening 119OP of the second pixel protection layer 119 may also be formed in an area corresponding to the pixel electrode 210.

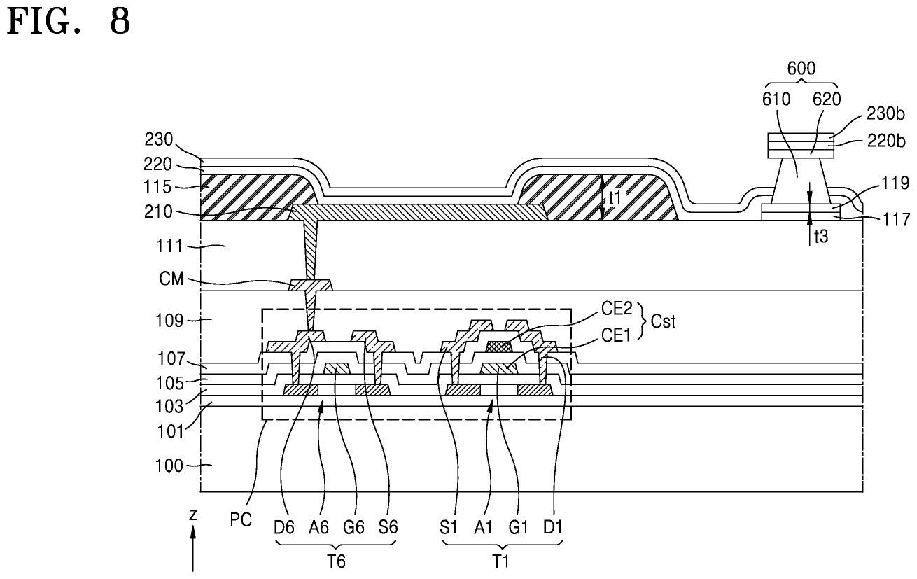

FIG. 8 is a cross-sectional view schematically illustrating a display apparatus 1 according to another embodiment.

The display apparatus 1 according to another embodiment may include an auxiliary electrode 600. The opposite electrode 230 may be entirely deposited over the substrate 100 without using a separate mask. Also, the opposite electrode 230 may be electrically connected to the common power supply line 16 (see FIG. 2) to receive the common voltage ELVSS. However, due to the internal resistance of the opposite electrode 230, a voltage drop may occur as the distance from the common power supply line 16 (see FIG. 2) increases. Thus, the auxiliary electrode 600 may be arranged to compensate for this.

For example, the display apparatus 1 may further include power lines (not illustrated) extending from the common power supply line 16 (see FIG. 2) to the display area DA. In an embodiment, the power lines may have a mesh structure in which they intersect each other in the display area DA. The auxiliary electrode 600 may be electrically connected to the power lines to receive the common voltage ELVSS from the common power supply line 16 (see FIG. 2) and transmit the common voltage ELVSS to the opposite electrode 230.

Referring to FIG. 8, the auxiliary electrode 600 may be arranged to be spaced apart from the pixel electrode 210. The pixel definition layer 115 may not be arranged in an area adjacent to the auxiliary electrode 600. In other words, the pixel definition layer 115 may include an opening portion in an area corresponding to the auxiliary electrode 600. However, the disclosure is not limited thereto and the auxiliary electrode 600 may be disposed over the pixel definition layer 115.

In another embodiment, the pixel definition layer 115 and the second organic insulating layer 111 may not be arranged in an area adjacent to the auxiliary electrode 600. That is, the pixel definition layer 115 and the second organic insulating layer 111 may include an opening portion in the area corresponding to the auxiliary electrode 600. In this case, the auxiliary electrode 600 may be arranged on the same layer as the connection metal CM.

The auxiliary electrode 600 may have a stack structure including a plurality of conductive layers. The auxiliary electrode 600 may include a main electrode layer 610 and an upper auxiliary electrode layer 620 disposed over the main electrode layer 610.

The main electrode layer 610 may be thicker than the upper auxiliary electrode layer 620. The main electrode layer 610 may include a conductive material such as copper (Cu), aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), and/or molybdenum (Mo). The main electrode layer 610 may have a single-layer or multiple-layer structure including the above material.

The main electrode layer 610 may have a shape in which the width thereof increases toward the lower portion thereof (the portion close to the substrate 100). That is, the side surface of the main electrode layer 610 may include a forward-tapered inclined surface. However, the disclosure is not limited thereto. The main electrode layer 610 may have any shape capable of transmitting the common voltage ELVSS to the opposite electrode 230.

The upper auxiliary electrode layer 620 may be disposed over the main electrode layer 610 and may include a different material than the main electrode layer 610. The upper auxiliary electrode layer 620 may prevent the main electrode layer 610 from being damaged during the display apparatus manufacturing process. The upper auxiliary electrode layer 620 may include a transparent conductive oxide (TCO) or may include a metal material such as titanium (Ti), molybdenum (Mo), and/or tungsten (W). Alternatively, the upper auxiliary electrode layer 620 may have a multilayer structure including a metal layer and a TCO layer described above.

The width of the upper auxiliary electrode layer 620 may be greater than the width of the main electrode layer 610 at the interface between the upper auxiliary electrode layer 620 and the main electrode layer 610. That is, the auxiliary electrode 600 may have an undercut shape. In other words, the upper auxiliary electrode layer 620 of the auxiliary electrode 600 may include a tip protruding to the outside of the main electrode layer 610.

A dummy intermediate layer 220b may be disposed over the upper auxiliary electrode layer 620, and a dummy opposite electrode 230b may be disposed over the dummy intermediate layer 220b.

The opposite electrode 230 may be electrically connected to the main electrode layer 610. In an embodiment, the opposite electrode 230 may contact the side surface of the main electrode layer 610. Particularly, due to the tip of the upper auxiliary electrode layer 620, the intermediate layer 220 may not be formed on the side surface of the main electrode layer 610 to completely cover the side surface of the main electrode layer 610. The opposite electrode 230 may extend to the side surface of the main electrode layer 610 where the intermediate layer 220 is not formed and thus may directly contact the main electrode layer 610. Because the opposite electrode 230 is electrically connected to the main electrode layer 610, the common voltage ELVSS may be provided through the main electrode layer 610.

A first pixel protection layer 117 and a second pixel protection layer 119 may be arranged between the auxiliary electrode 600 and the second organic insulating layer 111. The first pixel protection layer 117 may be disposed over the second organic insulating layer 111, and the second pixel protection layer 119 may be disposed over the first pixel protection layer 117.

As described with reference to FIG. 4B, the first pixel protection layer 117 and the second pixel protection layer 119 may be formed over the entire surface of the substrate 100 to cover the pixel definition layer 115 and the pixel electrode 210 and then remain only in an area overlapping the auxiliary electrode 600 through an etching process.

The first pixel protection layer 117 may prevent the pixel electrode 210 from being damaged by gas or liquid materials used in various etching processes or ashing processes included in the display apparatus manufacturing process. The first pixel protection layer 117 may include a conductive oxide such as indium tin oxide (ITO), indium zinc oxide (IZO), indium gallium zinc oxide (IGZO), indium tin zinc oxide (ITZO), zinc oxide (ZnO), aluminum-doped zinc oxide (AZO), gallium-doped zinc oxide (GZO), zinc tin oxide (ZTO), gallium tin oxide (GTO), and fluorine-doped tin oxide (FTO).

The second pixel protection layer 119 may protect the first pixel protection layer 117. Particularly, the second pixel protection layer 119 may prevent or minimize the pixel electrode 210 under the first pixel protection layer 117 from being damaged because the first pixel protection layer 117 is unnecessarily etched in a subsequent process such as etching. The second pixel protection layer 119 may include a material with a different etch rate in an etching process than the first pixel protection layer 117. That is, the second pixel protection layer 119 and the first pixel protection layer 117 may have a good etch selectivity to an etchant used in an etching process. For example, the second pixel protection layer 119 may include at least one of silicon oxide, silicon nitride, and silicon oxynitride.

A thickness t3 of the second pixel protection layer 119 may be about 900 angstroms or less. In an embodiment, the thickness t3 of the second pixel protection layer 119 may be about 100 angstroms to about 900 angstroms, about 300 angstroms to about 600 angstroms, or about 300 angstroms to about 500 angstroms. In an embodiment, the thickness t3 of the second pixel protection layer 119 may be about 500 angstroms. In an embodiment, the thickness t3 of the second pixel protection layer 119 may be less than the thickness t1 of the pixel definition layer 115. For example, the thickness t1 of the pixel definition layer 115 may be about 1,000 angstroms, and the thickness t3 of the second pixel protection layer 119 may be about 500 angstroms.

In an embodiment, the first pixel protection layer 117 and the second pixel protection layer 119 may cover the pixel electrode 210 to prevent the pixel electrode 210 from being damaged during an etching process for forming the auxiliary electrode 600. The etching process for forming the auxiliary electrode 600 may include a dry etching process for removing a portion of the main electrode layer 610 and a portion of the upper auxiliary electrode layer 620 by using a photoresist as a mask. During the dry etching process, the second pixel protection layer 119 may protect the first pixel protection layer 117 disposed under the second pixel protection layer 119.

An etching process for forming an auxiliary layer may include a process of wet-etching the main electrode layer 610 to form an undercut structure of the auxiliary electrode 600. When an undercut structure is formed by removing a portion of the main electrode layer 610, the second pixel protection layer 119 may protect the first pixel protection layer 117 under the second pixel protection layer 119.

Thereafter, a portion of the second pixel protection layer 119 may be removed through a dry etching process. When a portion of the second pixel protection layer 119 is removed, the first pixel protection layer 117 may protect the pixel electrode 210 under the first pixel protection layer 117. In this case, the second pixel protection layer 119 located under the auxiliary electrode 600 may remain without being removed. In this case, the second pixel protection layer 119 overlapping the auxiliary electrode 600 may remain without being removed.

Thereafter, a portion of the first pixel protection layer 117 may be removed by using a material for selectively etching the first pixel protection layer 117. The upper surface of the pixel definition layer 115 and the pixel electrode 210 may be exposed by removing the first pixel protection layer 117. In this case, the first pixel protection layer 117 located under the second pixel protection layer 119, that is, the first pixel protection layer 117 overlapping the auxiliary electrode 600, may remain without being removed.

In the plan view, the first pixel protection layer 117 and the second pixel protection layer 119 may have a shape corresponding to the auxiliary electrode 600. Here, “A has a shape corresponding to B” may mean that the shapes of A and B are substantially the same as each other or that A has a more or less etched shape than B due to the difference between the properties of the materials included therein.

In the present embodiment, in the etching process for forming the undercut structure of the auxiliary electrode 600, the first pixel protection layer 117 and the second pixel protection layer 119 may prevent or reduce damage to the layers under disposed the first pixel protection layer 117, for example, the pixel electrode 210 and the like.

As described above, according to an embodiment, a display manufacturing method capable of preventing an opposite electrode or a pixel electrode from being damaged during a display manufacturing process may be implemented. However, the scope of the disclosure is not limited to these effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a pixel electrode;
a pixel definition layer disposed over the pixel electrode and including a first opening exposing a center portion of the pixel electrode;
a bank layer disposed over the pixel definition layer and including a second opening exposing the center portion of the pixel electrode;
a first pixel protection layer and a second pixel protection layer arranged between the pixel definition layer and the bank layer;
an intermediate layer disposed over the pixel electrode;
an opposite electrode disposed over the intermediate layer; and
an encapsulation layer disposed over the bank layer and the opposite electrode.

2. The display apparatus of claim 1, further comprising a dummy intermediate layer and a dummy opposite electrode located between the bank layer and the encapsulation layer,
wherein the dummy intermediate layer comprises the same material as the intermediate layer, and
the dummy opposite electrode comprises the same material as the opposite electrode.

3. The display apparatus of claim 1, wherein the bank layer comprises a first subbank layer and a second subbank layer disposed over the first subbank layer,
wherein the first subbank layer includes a first subopening exposing the center portion of the pixel electrode,
wherein the second subbank layer includes a second subopening exposing the center portion of the pixel electrode, and
wherein the second subbank layer includes a tip protruding toward a center of the first subopening from a point where a side surface of the first subbank layer and a bottom surface of the second subbank layer meet each other.

4. The display apparatus of claim 3, wherein the first subbank layer and the second subbank layer comprise different materials.

5. The display apparatus of claim 3, wherein the opposite electrode directly contacts a side surface of the first subbank layer.

6. The display apparatus of claim 3, wherein a width of the first subopening at an interface between the first subbank layer and the second subbank layer is greater than a width of the first subopening at an interface between the first subbank layer and the second pixel protection layer.

7. The display apparatus of claim 3, wherein the tip surrounds the center portion of the pixel electrode.

8. The display apparatus of claim 1, wherein the first pixel protection layer and the second pixel protection layer comprise materials with different etch rates.

9. The display apparatus of claim 1, wherein the first pixel protection layer comprises conductive oxide and the second pixel protection layer comprises silicon oxide, silicon nitride, or silicon oxynitride.

10. A method of manufacturing a display apparatus, the method comprising:
forming a pixel electrode over a substrate;
forming a pixel definition layer including a first opening exposing a center portion of the pixel electrode over the pixel electrode;
forming a first pixel protection layer over the pixel definition layer and the pixel electrode;
forming a second pixel protection layer over the first pixel protection layer;
forming a bank layer over the second pixel protection layer;
sequentially removing a portion of the bank layer, a portion of the second pixel protection layer, and a portion of the first pixel protection layer to expose the center portion of the pixel electrode;
forming an intermediate layer over the pixel electrode;
forming an opposite electrode over the intermediate layer; and
forming an encapsulation layer over the opposite electrode.

11. The method of claim 10, wherein the forming of the bank layer comprises:
forming a first subbank layer over the second pixel protection layer; and
forming a second subbank layer over the first subbank layer, and
wherein the removing of a portion of the bank layer comprises removing a portion of the first subbank layer and a portion of the second subbank layer such that the second subbank layer includes a tip protruding toward the center portion of the pixel electrode from a point where a side surface of the first subbank layer and a bottom surface of the second subbank layer meet each other.

12. The method of claim 11, wherein the opposite electrode directly contacts a side surface of the first subbank layer.

13. The method of claim 11, wherein the first subbank layer and the second subbank layer comprise different materials.

14. The method of claim 11, wherein the removing of a portion of the first subbank layer and a portion of the second subbank layer comprises forming a first subopening formed through the first subbank layer, and
wherein a width of the first subopening at an interface of the first subbank layer and the second subbank layer is greater than a width of the first subopening at an interface between the first subbank layer and the second pixel protection layer.

15. The method of claim 10, wherein the first pixel protection layer and the second pixel protection layer comprise materials with different etch rates.

16. The method of claim 10, wherein the first pixel protection layer comprises conductive oxide and the second pixel protection layer comprises at least one of silicon oxide, silicon nitride, and silicon oxynitride.

17. A display apparatus comprising:
a pixel electrode;
a pixel definition layer disposed over the pixel electrode and including an opening exposing a center portion of the pixel electrode;
an auxiliary electrode disposed to be spaced apart from the pixel electrode;
a first pixel protection layer and a second pixel protection layer arranged below the auxiliary electrode;
an intermediate layer disposed over the pixel electrode; and
an opposite electrode disposed over the intermediate layer,
wherein the auxiliary electrode is electrically connected to the opposite electrode.

18. The display apparatus of claim 17, wherein the auxiliary electrode comprises a main electrode layer and an upper auxiliary electrode layer disposed over the main electrode layer, and
wherein a width of the upper auxiliary electrode layer is greater than a width of the main electrode layer at an interface between the upper auxiliary electrode layer and the main electrode layer.

19. The display apparatus of claim 18, wherein a side surface of the main electrode layer and the opposite electrode contact each other.

20. The display apparatus of claim 18, wherein the first pixel protection layer comprises conductive oxide, and the second pixel protection layer comprises silicon oxide, silicon nitride, or silicon oxynitride.
